(19) United States
(12) Patent Application Publication
(10) Pub. No.: US 2026/0136800 A1
(43) Pub. Date: May 14, 2026

(54) LIGHT EMITTING DISPLAY DEVICE

(71) Applicant: LG Display Co., Ltd., Seoul (KR)

(72) Inventor: Sung Ji YOON, Paju-si (KR)

(21) Appl. No.: 19/376,350

(22) Filed: Oct. 31, 2025

(30) Foreign Application Priority Data
Nov. 8, 2024 (KR) 10-2024-0158417

(51) Int. Cl. H10K 59/38; H10K 59/122; H10K 59/35

(52) U.S. Cl. CPC H10K 59/38; H10K 59/122; H10K 59/353

(57) ABSTRACT

A light emitting display device including a substrate with a red subpixel, a green subpixel, and a blue subpixel, each having an emission portion and a non-emission portion, a bank at the non-emission portions of the red subpixel, the green subpixel, and the blue subpixel, a light emitting element at each of the red subpixel, the green subpixel, and the blue subpixel, an encapsulation layer covering the light emitting element of each of the red, green, and blue subpixels, and a color filter located on the encapsulation layer and overlapping the emission portion of each of the red, green, and blue subpixels, and a reflective layer located between the bank and the color filter and overlapping at least the bank.

### CROSS REFERENCE TO RELATED APPLICATIONS

Pursuant to 35 U.S.C. § 119(a), this application claims the benefit of an earlier filing date and right of priority to Korean Patent Application No. 10-2024-0158417, filed on November 8, 2024, the entire contents of which are hereby incorporated by reference for all purpose as if fully set forth herein.

### TECHNICAL FIELD

The present disclosure generally relates to a display device.

### BACKGROUND

As the information society develops, the demand for display devices for displaying images is increasing in various forms.

A light emitting display device having pixels including light emitting elements does not require a separate light source unit and is thus advantageous in slimness or flexibility, and has good color purity.

For example, a light emitting element includes two different electrodes and an emission layer between the electrodes, and when electrons generated from one electrode and holes generated from the other electrode are injected into the emission layer, the injected electrons and holes are combined, generating excitons, and as the generated excitons fall from the excited state to the ground state, light is emitted.

The description provided in the background section should not be assumed to be prior art merely because it is mentioned in or associated with the background section. The background section may include information that describes one or more aspects of the subject technology.

### SUMMARY

In one aspect of the present disclosure, a light emitting display device may include a substrate including a red subpixel, a green subpixel, and a blue subpixel, each having an emission portion and a non-emission portion, a bank at the non-emission portions of the red subpixel, the green subpixel, and the blue subpixel, a light emitting element at each of the red subpixel, the green subpixel, and the blue subpixel, an encapsulation layer covering the light emitting element of each of the red subpixel, the green subpixel, and the blue subpixel, a color filter located on the encapsulation layer and overlapping the emission portion of each of the red subpixel, the green subpixel, and the blue subpixel, and a reflective layer located between the bank and the color filter and overlapping at least the bank.

In another aspect of the present disclosure, a light emitting display device may include a substrate including a first subpixel, a second subpixel and a third subpixel, each having an emission portion and a non-emission portion, a bank provided at the non-emission portions of the first to third subpixels, a light emitting element provided at each of the first to third subpixels, an encapsulation layer covering the light emitting element of each of the first to third subpixels, a color filter located on the encapsulation layer and overlapping the emission portion of each of the first to third subpixels, and a reflective layer located between the bank and the color filter and configured to reflect external light that passes through the color filter back toward the color filter.

In yet another aspect of the present disclosure, a light emitting display device may include a substrate including a first subpixel, a second subpixel and a third subpixel, each having an emission portion and a non-emission portion; a light emitting element provided at each of the first to third subpixels; a color filter located over the light emitting element of each of the first to third subpixels and disposed to overlap the emission portions of the first to third subpixels; and a reflective layer disposed within the non-emission portions of the first to third subpixels and having openings exposing the emission portions of the first to third subpixels.

According to example implementations of the present disclosure, the light emitting display device can help prevent external light from being reflected even without a polarizer which can reduce light transmittance, while improving initial image quality.

According to example implementations of the present disclosure, the light emitting display device can make the lifespan characteristics of red, green, and blue subpixels uniform.

According to example implementations of the present disclosure, the light emitting display device can help prevent visibility of a specific color from being prominent not only at the initial stage of operation but also after a certain period of operation.

It is to be understood that both the foregoing general description and the following detailed description of the present disclosure are examples and explanatory and are intended to provide further explanation of the disclosure as claimed.

### BRIEF DESCRIPTION OF THE DRAWINGS

FIG. 1 is a plan view schematically showing an example of a light emitting display device according to one implementation of the present disclosure;

FIG. 2 is a plan view showing an example of the arrangement of subpixels of a light emitting display device according to an example implementation of the present disclosure;

FIG. 3 is a plan view showing an example of the arrangement of subpixels of a light emitting display device according to another example implementation of the present disclosure;

FIGS. 4 to 6 are cross-sectional views taken along line I-I’ of FIG. 2 of an example of light emitting display devices according to various example implementations of the present disclosure;

FIG. 7 is a coordinate system showing an example of the external light reflection visibilities of a light emitting display devices according to an example implementation of the present disclosure and a light emitting display device according to a comparative example;

FIG. 8 is a view showing an example of a light emitting display device according to another example implementation of the present disclosure; and

FIG. 9 is a view showing an example of a light emitting display device according to yet another implementation of the present disclosure.

### DETAILED DESCRIPTION

Implementations of the present disclosure can provide a light emitting display device having improved initial image quality and lifespan balance with respect to changes over time, in a structure in which an anti-reflection structure including a light shielding layer and color filters is employed in place of a polarizer.

Some implementations of the present disclosure can provide a light emitting display device that prevents external light from being reflected without a polarizer, which reduces light transmittance, and simultaneously improves initial image quality.

Some implementations of the present disclosure can provide a light emitting display device that makes the lifespan characteristics of red, green, and blue subpixels similar or uniform.

Some implementations of the present disclosure can provide a light emitting display device that prevents visibility of a specific color from being prominent not only at the initial stage of operation but also after a certain period of operation.

Additional advantages, aspects, and features of the disclosure will be set forth in part in the description which follows and in part will become apparent to those having ordinary skill in the art upon examination of the following or may be learned from practice of the disclosure. The aspects and other advantages of the disclosure may be realized and attained by the structure particularly pointed out in the written description and claims hereof as well as the appended drawings.

Hereinafter, example implementations of the present disclosure will be described with reference to the accompanying drawings. Reference will now be made in detail to example implementations of the present disclosure, examples of which are illustrated in the accompanying drawings. Wherever possible, the same reference numbers will be used throughout the drawings to refer to the same or like parts, unless otherwise specified. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure, and a method of achieving the advantages and features will become apparent with reference to the example implementations described herein in detail together with the accompanying drawings. The present disclosure should not be construed as limited to the example implementations as disclosed below, and can be embodied in various different forms. Thus, these example implementations are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations may be omitted. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example implementations of the present disclosure are merely given by way of example. The disclosure is not limited to the illustrations in the drawings. Any implementation described herein as an “example” is not necessarily to be construed as preferred or advantageous over other implementations.

In the present specification, where terms such as “including,” “having,” “comprising,” and the like are used, one or more components can be added, unless a more limiting term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example implementations of the present disclosure, where the positional relationship between two elements is described using terms, such as “on”, “above”, “under” and “next to”, at least one intervening element can be present between the two elements, unless a more limiting term such as “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present. Furthermore, the terms “left,” “right,” “top,” “bottom, “downward,” “upward,” “upper,” “lower,” and the like refer to an arbitrary frame of reference.

In describing the various example implementations of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example implementations of the present disclosure, terms such as “first,” “second,” “A,” “B,” “(a),” and “(b),” can be used to describe a variety of components. These terms aim to distinguish the same or similar components from one another and do not limit the essence, sequence, order, or number of components. Accordingly, throughout the specification, a “first” component can be the same as a “second” component within the technical concept of the present disclosure, unless specifically mentioned otherwise.

Features of various implementations of the present disclosure can be partially or overall coupled to or combined with each other, and can be variously inter-operated with each other and driven technically as those skilled in the art can sufficiently understand. The implementations of the present disclosure can be carried out independently from each other, or can be carried out together in a co-dependent relationship.

Unless otherwise defined, all terms (including technical and scientific terms) used herein have the same meaning as commonly understood by one of ordinary skill in the art to which example implementations belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt%, or when the p-type material is present in an amount of less than 30 wt%, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example implementations of the present disclosure will be described in detail with reference to the accompanying drawings. In adding reference numerals to elements of each of the drawings, although the same elements are illustrated in other drawings, like reference numerals can refer to like elements. Further, for convenience of description, a scale in which each of elements is illustrated in the accompanying drawings can differ from an actual scale. Thus, the illustrated elements are not limited to the specific scale in which they are illustrated in the drawings.

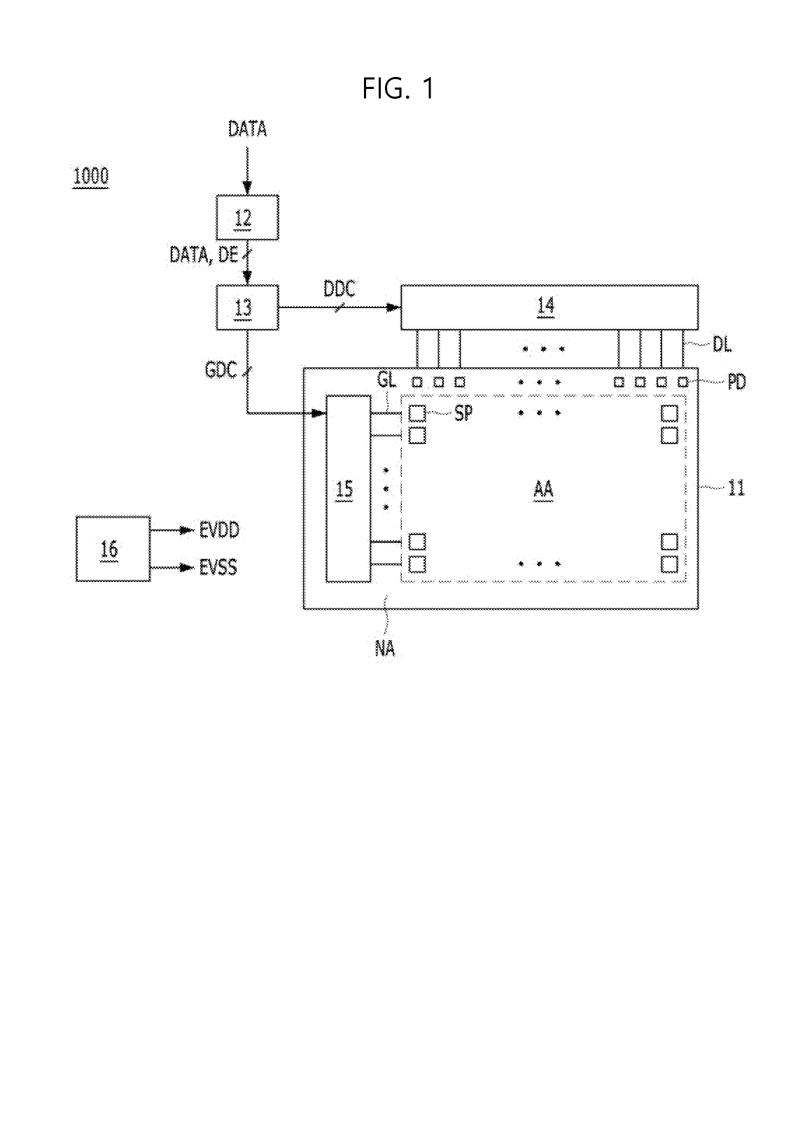

FIG. 1 is a block diagram schematically showing a light emitting display device according to an example implementation of the present disclosure.

As shown in FIG. 1, a light emitting display device 1000 according to one implementation of the present disclosure may include a display panel 11, and one or more of an image processor 12, a timing controller 13, a data driver 14, a scan driver 15, and a power supply 16.

The display panel 11 may display an image in response to a data signal DATA supplied from the data driver 14, a scan signal supplied from the scan driver 15, and power supplied from the power supply 16.

The display panel 11 may include a subpixel SP disposed at each of intersections of a plurality of gate lines GL and a plurality of data lines DL. The structure of subpixels SP may vary depending on the type of the light emitting display device 1000.

For example, the subpixels SP may be formed in a top emission type, a bottom emission type, or a dual emission type depending on the structure. The subpixels SP refer to units that may be provided with a specific type of color filter or emit a specific color without a color filter. For example, the subpixels SP may include a red subpixel, a green subpixel, and a blue subpixel. Alternatively, the subpixels SP may include, for example, a red subpixel, a blue subpixel, a white subpixel, and a green subpixel. The subpixels SP may have one or more different emission areas depending on light emitting characteristics. For example, subpixels that emit different colors may have different emission areas.

One or more subpixels SP may constitute one unit pixel. For example, one unit pixel may include red, green, and blue subpixels, and the red, green, and blue subpixels may be repeatedly arranged. Alternatively, one unit pixel may include red, green, blue, and white subpixels, and the red, green, blue, and white subpixels may be arranged in a repeating manner, or the red, green, blue, and white subpixels may be arranged in a quad type. In one implementation according to the present disclosure, the color type, arrangement type, arrangement order, etc. of the subpixels SP may be configured in various forms depending on the light emitting characteristics, the lifespan of the elements, the specifications of the device, etc., without being limited thereto.

The display panel 11 may be divided into a display area AA (area inside a dotted line) where the subpixels SP are arranged to display an image, and a non-display area NA adjacent to (for example, surrounding) the display area AA. The scan driver 15 may be mounted in the non-display area NA of the display panel 11. In addition, the non-display area NA may include a pad part PAD including pad electrodes PD.

Here, the display area AA may be referred to as an active area AA, and the non-display area NA may be referred to as a non-active area NA.

The image processor 12 may output a data enable signal DE, and the like, in addition to the data signal DATA supplied from the outside. In addition to the data enable signal DE, the image processor 12 may output one or more of a vertical synchronization signal, a horizontal synchronization signal, and a clock signal, but these driving signals are omitted for convenience of explanation.

The timing controller 13 may receive the data signal DATA in addition to a driving signal from the image processor 12. The driving signal may include the data enable signal DE. Alternatively, the driving signal may include the vertical synchronization signal, the horizontal synchronization signal, and the clock signal. The timing controller 13 may output a data timing control signal DDC for controlling the operation timing of the data driver 14 and a gate timing control signal GDC for controlling the operation timing of the scan driver 15 based on the driving signal.

The data driver 14 may sample and latch the data signal DATA supplied from the timing controller 13 in response to the data timing control signal DDC supplied from the timing controller 13, convert the sampled and latched data signal into a gamma reference voltage, and output the gamma reference voltage.

The data driver 14 may output the data signal DATA through the data lines DL. The data driver 14 may be implemented in the form of an integrated circuit (IC). For example, the data driver 14 may be electrically connected to the pad electrodes PD disposed in the non-active area NA of the display panel 11 through a flexible circuit layer (not shown).

The scan driver 15 may output the scan signal in response to the gate timing control signal GDC supplied from the timing controller 13. The scan driver 15 may output the scan signal through the gate lines GL. The scan driver 15 may be implemented in the form of an integrated circuit (IC) or implemented in the display panel 11 in a Gate-In-Panel (GIP) manner, but the present disclosure is not limited thereto.

The power supply 16 may output a high-potential voltage and a low-potential voltage for driving the display panel 11. The power supply 16 may supply the high-potential voltage to the display panel 11 through a first power line EVDD (a driving power line or a pixel power line), and may supply the low-potential voltage to the display panel 11 through a second power line EVSS (an auxiliary power line or a common power line).

The display panel 11 may be divided into the active area AA and the non-active area NA, and may include the plurality of subpixels SP defined by the gate lines GL and the data lines DL that intersect each other and are formed in a matrix form within the active area AA.

The subpixels SP may include subpixels that emit at least two or more colors of light among red light, green light, blue light, yellow light, magenta light, and cyan light. In addition, the plurality of subpixels SP may have a specific type of color filter formed thereon, or may emit light of a specific color without a color filter. However, the present disclosure is not limited thereto, and the color type, arrangement type, arrangement order, etc. of the subpixels SP may be configured in various forms depending on the light emitting characteristics, the lifespan of the elements, the specifications of the device, etc.

Each of the subpixels SP may include an emission portion that emits light and a non-emission portion around the emission portion.

Hereinafter, a light emitting display device to which a light emitting element including an emission layer that emits a corresponding color is applied to each of the red subpixel, the green subpixel, and the blue subpixel according to one implementation of the present disclosure will be described by way of example only with reference to the drawings, and the present disclosure is not limited thereto.

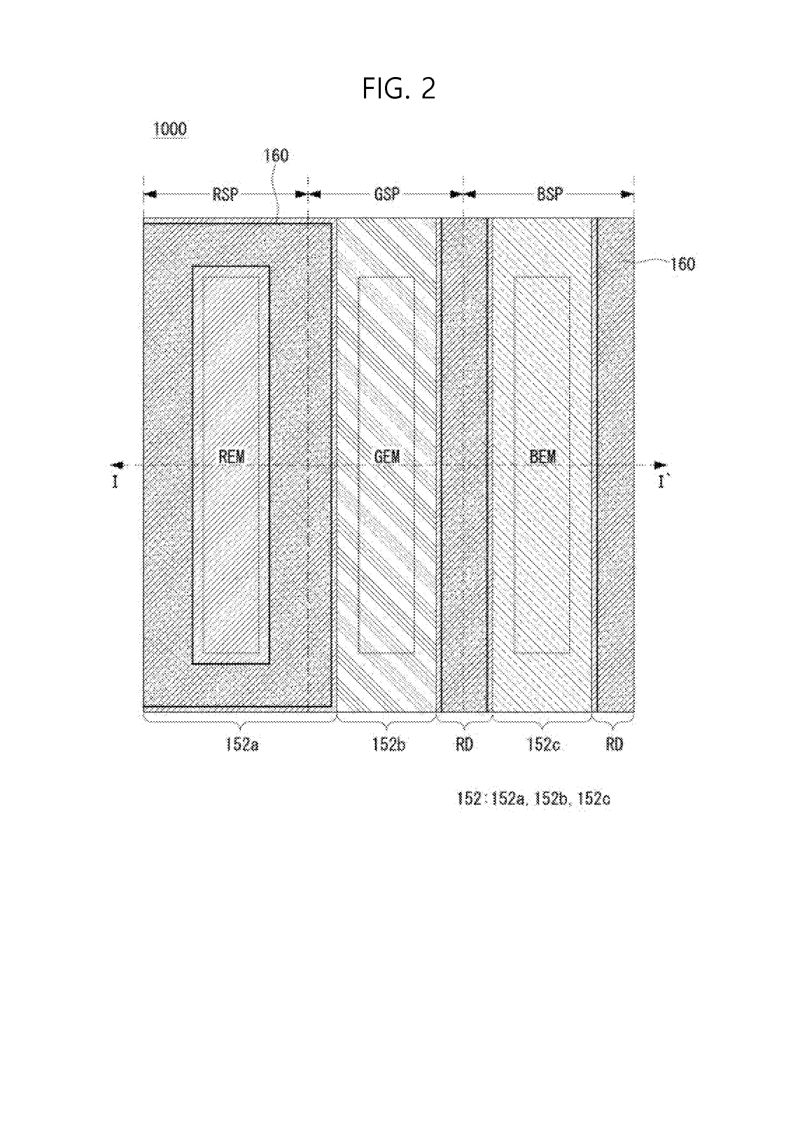

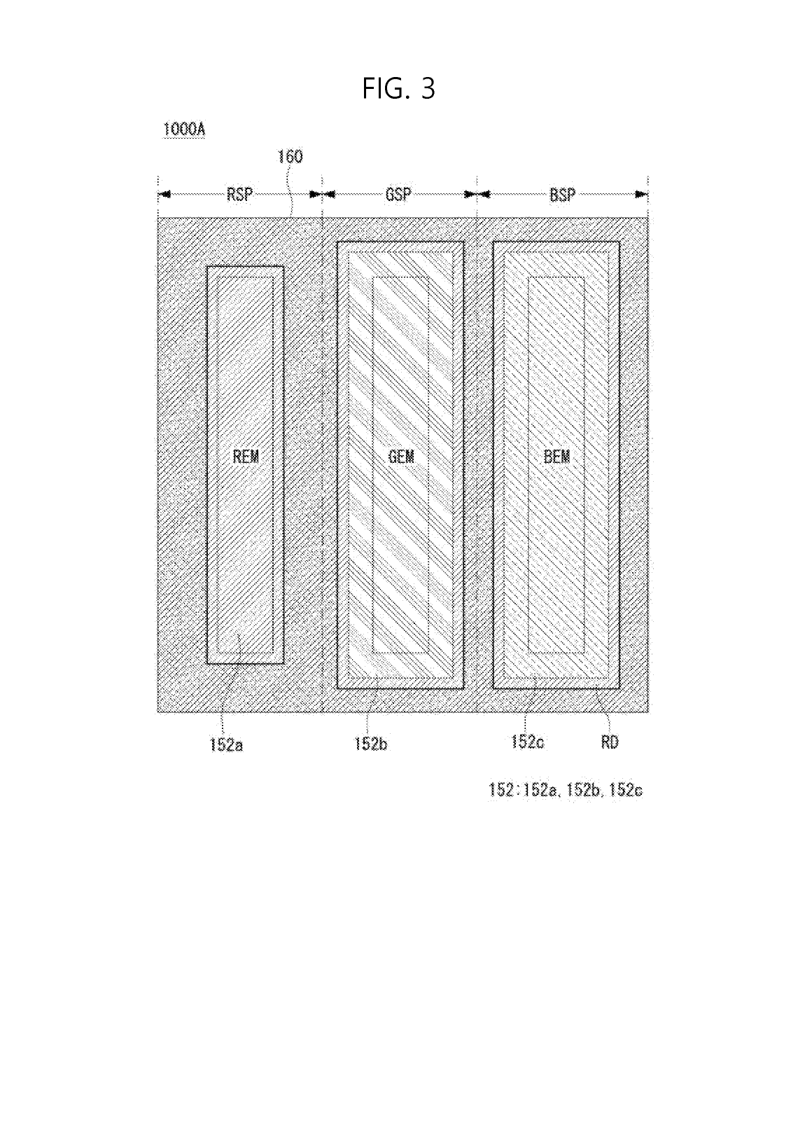

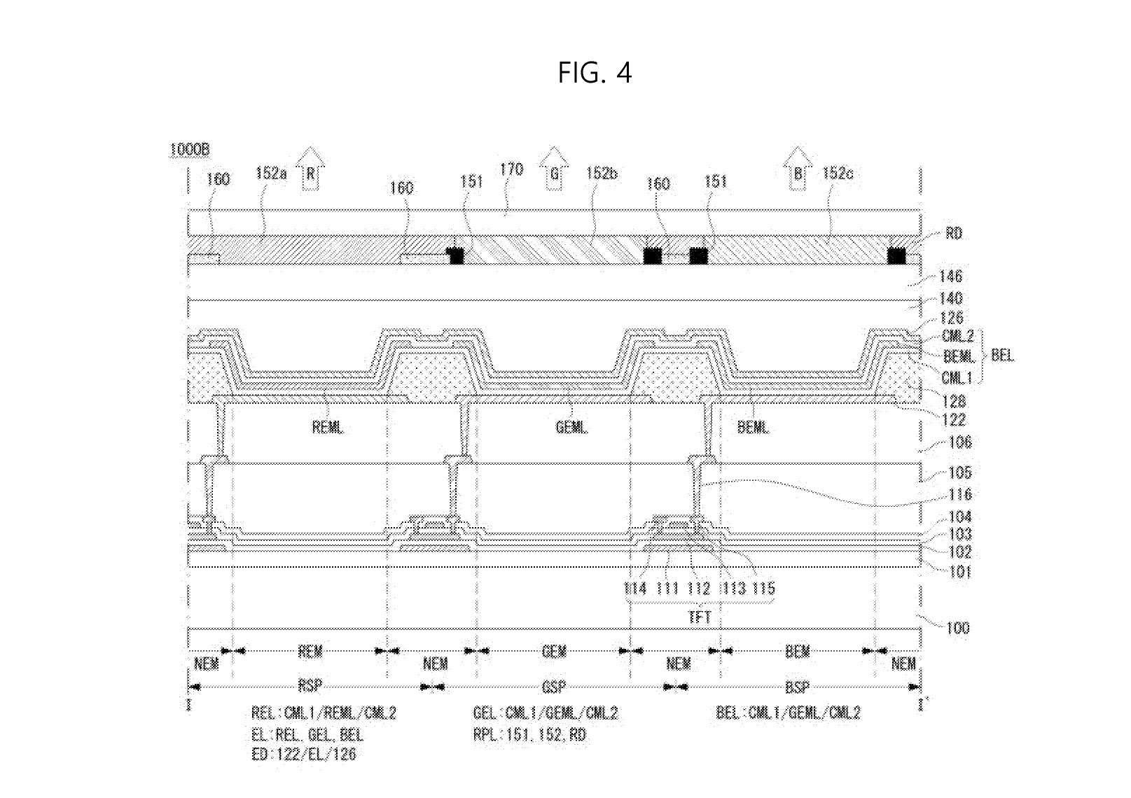

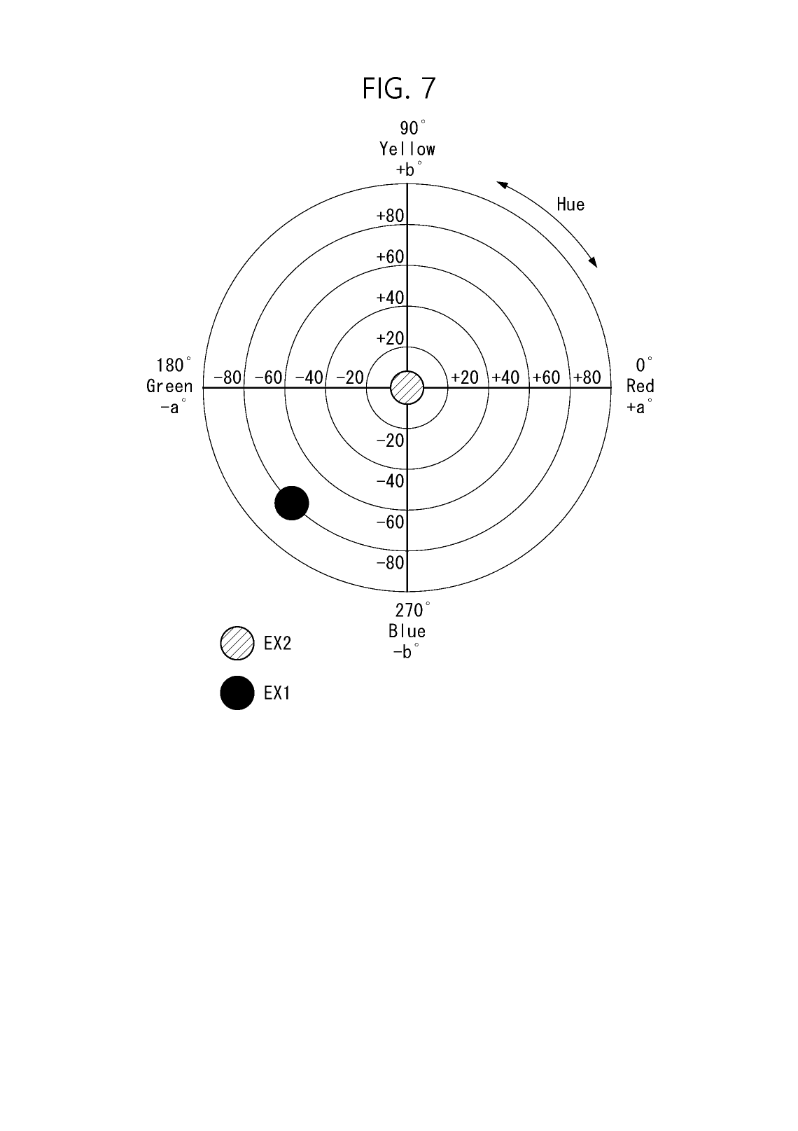

FIG. 2 is a plan view showing the arrangement of subpixels of a light emitting display device according to an example implementation (which may be a first implementation) of the present disclosure. FIG. 3 is a plan view showing the arrangement of subpixels of a light emitting display device according to another example implementation (which may be a second implementation) of the present disclosure. FIGS. 4 to 6 are cross-sectional views taken along line I-I’ of FIG. 2 of light emitting display devices according to various implementations of the present disclosure. FIG. 7 is a coordinate system showing the external light reflection visibilities of a light emitting display devices according to one implementation of the present disclosure and a light emitting display device according to a comparative example.

FIGS. 2 and 3 show the arrangements of a reflective layer 160 and color filters 152: 152a, 152b, and 152c according to the implementations of the present disclosure, and FIGS. 4 to 6 show cross-sectional configurations of light emitting display devices according to various implementations of the present disclosure.

First, referring to FIGS. 2 and 4, a light emitting display device according to one implementation of the present disclosure will be described.

As shown in FIGS. 2 and 4, a light emitting display device 1000 according to the first implementation of the present disclosure includes a substrate 100 including a red subpixel RSP, a green subpixel GSP, and a blue subpixel BSP, each having an emission portion REM, GEM, or BEM and a non-emission portion NEM, a bank 128 provided in the non-emission portions NEM of the red subpixel RSP, the green subpixel GSP, and the blue subpixel BSP, a light emitting element ED provided in each of the red subpixel RSP, the green subpixel GSP, and the blue subpixel BSP, an encapsulation layer 140 that covers the light emitting elements ED, an anti-reflection structure RPL located on the encapsulation layer 140, and a reflective layer 160 located between the upper surface of the bank 128 and the anti-reflection structure RPL and configured to overlap the bank 128.

The anti-reflection structure RPL serves to prevent external light that enters from the outside of the anti-reflection structure RPL from entering the light emitting elements ED and being reflected by electrodes of the light emitting elements ED and recognized.

The anti-reflection structure RPL is located on the encapsulation layer 140 close to a side on which the external light is incident. The anti-reflection structure RPL includes a light shielding layer 151 that overlaps the non-emission portions NEM, and color filters 152: 152a, 152b, and 152c that are located on the encapsulation layer 140 and overlap the emission portions REM, GEM, and BEM.

In addition, the anti-reflection structure RPL may further include a dummy red color filter RD, thereby being capable of increasing the reflection efficiency of external light with red wavelengths not only in the non-emission portion of the red subpixel but also in the non-emission portions of other subpixels, and increasing the amount of red light passing through these portions. For example, as shown in FIG. 4, the dummy red color filter RD may be disposed in in the non-emission portions NEM of the red subpixel RSP, the green subpixel GSP, and the blue subpixel BSP, and thus may be overlapped with the bank 128 or the reflective layer 160. In the red subpixel RSP, the dummy red color filter RD and the red color filter 152a may be integrated with each other.

The anti-reflection structure RPL may utilize the absorption property of the light shielding layer 151 for light in the entire visible spectrum.

The color filters 152: 152a, 152b, and 152c and the dummy red color filter RD utilize selective transmissibility for light of specific wavelengths. The color filters 152: 152a, 152b, and 152c at least corresponding to the emission portions REM, GEM, and BEM may absorb light of a wavelength range other than light of the selected wavelengths, and may also enable emission of light of the selected wavelength from the light emitting element ED provided in each subpixel.

Specifically, the light shielding layer 151 is located in the non-emission portions NEM and may have a function of absorbing light in the traveling direction of light. The light shielding layer 151 may include black particles in a binder and/or a solvent, and be provided to correspond to the non-emission portions NEM. The black particles may include an organic black material, a metal oxide, or the like. The organic black material may include, for example, carbon black, lactam black, or perylene black. The metal oxide may include, for example, TiNₓO_{y} or CuMnFeOₓ. The thickness of the light shielding layer 151 may be adjusted depending on the size of the black particles included in the light shielding layer 151. The light shielding layer 151 may be provided at the boundaries between a red color filter 152a, a green color filter 152b, and a blue color filter 152c corresponding to the respective subpixels.

The light emitting display device 1000 according to the implementation of FIG. 2 shows an example in which the red color filter 152a, the green color filter 152b, and the blue color filter 152c are provided in a stripe shape, but the present disclosure is not limited thereto.

The red color filter 152a and the red dummy color filter RD may transmit light having wavelengths of 600 nm to 650 nm, the green color filter 152b may transmit light having wavelengths of 510 nm to 590 nm, and the blue color filter 152c may transmit light having wavelengths of 430 nm to 495 nm, but the present disclosure is not limited thereto.

Here, the red color filter 152a may extend laterally to have a longer width than the entire width of the red subpixel RSP. In this case, the red color filter 152a may be in contact with the blue color filter 152c and the green color filter 152b on both sides. The red color filter 152a may overlap the entire area of the emission portion NEM disposed in the active area AA of the light emitting display device 1000 with a larger width than the green color filter 152b and the blue color filter 152c.

The dummy red color filter RD may be formed of the same material as the red color filter 152a and may have the same red light transmittance. Further, the dummy red color filter RD may be disposed to be spaced apart from the red color filter 152a, as shown in FIG. 2.

The reflective layer 160 is located to overlap the dummy red color filter RD and the red color filter 152a located in the non-emission portions NEM.

The reflective layer 160 includes a reflective electrode. The reflective layer 160 may be formed as a multilayer structure, such as a stacked structure (Ti/Al/Ti) of aluminum (Al) and titanium (Ti), a stacked structure (ITO/Al/ITO) of aluminum (Al) and ITO, an APC alloy (Ag/Pd/Cu), a stacked structure (ITO/APC/ITO) of an APC alloy and ITO, or a stacked structure (Ag/MoTi) of silver (Ag) and an molybdenum/titanium alloy, or may include a single layer structure formed of one material selected from silver (Ag), aluminum (Al), molybdenum (Mo), gold (Au), magnesium (Mg), calcium (Ca), and barium (Ba), or an alloy of two or more material selected therefrom. The reflective layer 160 has a function of improving red external light reflection visibility by overlapping the red color filter 152a or the dummy red color filter RD, due to the structure itself of the reflective layer 160 regardless of the electrical operation of the light emitting elements ED. The reflective layer 160 is electrically separated from first electrodes 122 and second electrodes 126 of the light emitting elements ED and is not affected by the electrical operation of the light emitting elements ED.

Specifically, in the light emitting display device 1000 according to one implementation of the present disclosure, as shown in FIG. 2, the red color filter 152a is integrally provided in the emission portion REM and the non-emission portion NEM of the red subpixel RSP, and in the green and blue subpixels GSP and BSP, the green color filter 152b and the blue color filter 152c may be provided at least in emission portions GEM and BEM and partially extend from at least the emission portions GEM and BEM to the non-emission portions NEM, respectively. Here, the green color filter 152b and the blue color filter 152c may be spaced apart from each other, and the dummy color filter RD may be placed in an area between the green color filter 152b and the blue color filter 152c. In addition, the blue color filter 152c may be spaced apart from the neighboring subpixels, and the red color filter 152a or the dummy red color filter RD may be disposed in an area by which the blue color filter 152c is spaced apart from the neighboring subpixel.

In addition, the reflective layer 160 may include a shape surrounding the red emission portion REM and a shape parallel to at least one side of each of the green emission portion GEM and the blue emission portion BEM, as shown in FIG. 2.

Among external light, red light having passed through the red color filter 152a and the dummy red color filter RD in the non-emission portions NEM is reflected upward from the reflective layer 160 by the reflective layer 160 overlapping the red color filter 152a and the dummy red color filter RD, thereby being capable of adjusting initial visibility of the light emitting display device 1000.

The light emitting display device 1000 according to one implementation of the present disclosure employs a reflection efficiency structure of a complementary color of cyan through overlapping between the extension of the red color filter 152a and the dummy red color filter RD of the anti-reflection structure RPL, and the reflective layer 160, even if light emitting display device 1000 exhibits a color biased to cyan, for example, in a configuration below the anti-reflection structure RPL. Thereby, degradation of visibility observed as a specific color is prevented when light is finally emitted after passing through the anti-reflection structure RPL. For example, an initial black state may be implemented as clear black, and when driving colors including white, a corresponding color may be implemented without being biased to a specific color. Therefore, the light emitting display device 1000 may obtain a high contrast ratio.

The light emitting display device 1000 according to one implementation of the present disclosure achieves visibility adjustment not by controlling the area of the emission portion, but by additionally controlling the extension of the red color filter and the dummy red color filter of the external light anti-reflection structure and the reflective layer. If an initial color defect is solved by increasing the area of the emission portion of a specific color subpixel, the lifespan of the subpixel with the increased color emission portion increases, thereby losing the red, green, and blue subpixel lifespan balance. The light emitting display device 1000 according to one implementation of the present disclosure supplements color insufficiencies in the initial state by increasing external light reflection efficiency by extending the red color filter over the external light reflective layer, and adding the dummy red color filter and the reflective layer overlapping the red color filter and the dummy red color filter without adjusting the area of the emission portion. Thereby, the light emitting display device 1000 according to one implementation of the present disclosure may maintain the red, green, and blue balance, and may maintain color temperature characteristics uniformly even over time.

Light emitting display devices are being developed while considering both the convenience of use and the transmittance of the devices. Since a light emitting display device includes a metal electrode in a light emitting element, a method of attaching a polarizer has been considered to prevent external light reflection due to reflection of external light by the metal electrode, but the polarizer greatly limits the amount of light emitted, and thus research on a method of omitting the polarizer is being conducted. In addition, for the purpose of achieving slimness and flexibility of the device and ease of application of the device to displays, light emitting display devices in which a color filter array for reproducing colors is applied to an encapsulation layer without using an additional encapsulation substrate or a counter substrate are being developed.

A light emitting display device employing a polarizer has a good effect of preventing reflection of external light between areas even in an environment with strong external light due to the light absorption property of the polarizer itself, but has a low light emission rate. In addition, since the polarizer, which is an optical layer, must be attached to the outside of the light emitting display device, it is difficult to achieve slimness of the device due to the increase in thickness and the increase in the number of processes due to the attachment of the polarizer.

Light emitting display devices of the implementations of the present disclosure are one of polarizer-less structures and have an anti-reflection structure for preventing reflection of external light. The anti-reflection structure includes a light shielding layer and color filters that perform color display, and functions to perform color reproduction and prevent external light from being recognized.

In FIGS. 2 or 3, the light shielding layer 151 that overlaps the color filters 152 is not illustrated for convenience. The light shielding layer 151 of the anti-reflection structure RPL may be disposed to overlap the boundaries between the subpixels, as shown in FIG. 4. In some cases, the light shielding layer 151 may be omitted. Referring to the configuration of the light emitting elements ED located below the anti-reflection structure RPL, as shown in FIG. 4, the bank 128 is open to the emission portions REM, GEM, and BEM, and is disposed in the non-emission portions NEM. If the bank 128 includes a black material, a light shielding effect may be obtained by the bank 128. In addition, when light is emitted from the light emitting elements ED, even if some light is emitted in a diagonal direction, the bank 128 may absorb the light and prevent color mixing between adjacent subpixels.

For example, as shown in FIG. 4, in a light emitting display device 1000B according to one implementation of the present disclosure, the light shielding layer 151 may overlap at least one color filter 152: 152a, 152b, or 152c.

The light shielding layer 151 not only blocks external light, but also absorbs light that spreads in a diagonal direction rather than a straight line among light emitted from the emission portions REM, GEM, and BEM in the emission direction, thereby preventing the light that spreads in the diagonal direction from the light emitting elements ED from passing through the non-emission portions REM, GEM, and BEM and entering the adjacent subpixels.

The color filters 152 may include the red color filter 152a overlapping the emission portion REM of the red subpixel and the non-emission portion NEM of the red subpixel, the green color filter 152b overlapping the emission portion GEM of the green subpixel GSP, and the blue color filter 152c overlapping the emission portion BEM of the blue subpixel BSP.

Further, the color filters 152: 152a, 152b, and 152c included in the anti-reflection structure RPL are located in the corresponding subpixels RSP, GSP, and BSP. The color filters 152: 152a, 152b, and 152c may absorb light of wavelengths for which the respective color filters 152a, 152b, and 152c do not have selective transmissibility, among incident light coming from the outside. For example, the red color filter 152a may transmit red light in an optical path and absorb green light and blue light, which are light of the remaining wavelengths. The green color filter 152b may transmit green light in an optical path and absorb red light and blue light, which are light of the remaining wavelengths. The blue color filter 152c may transmit blue light in an optical path and absorb red light and green light, which are light of the remaining wavelengths.

Each of the color filters 152: 152a, 152b, and 152c may include a color pigment having its own wavelength selection properties. The color pigment may be mixed with a solvent and applied to a corresponding one of the red subpixel RSP, green subpixel GSP, and blue subpixel BSP, the solvent may be evaporated to leave the corresponding color filter 152: 152a, 152b, or 152c having a color pigment component, and then, the color filters 152: 152a, 152b, and 152c may be patterned for each subpixel RSP, GSP, or BSP.

The color filters 152: 152a, 152b, and 152c may selectively transmit light wavelengths not only in a direction in which external light is incident but also in a direction in which light is emitted from the light emitting elements ED. For example, the color filter 152: 152a, 152b, or 152c transmits a color to be expressed in the corresponding subpixel among the emitted light, but absorbs light of the wavelengths of the remaining colors. For example, in the red subpixel RSP, the red color filter 152a transmits red light among light emitted from the light emitting element ED and emits the red light to the outside, while absorbing wavelengths of green light and blue light. Similarly, in the green subpixel GSP, the green color filter 152b transmits green light from light emitting element ED and emits the green light outward, while absorbing wavelengths of red light and blue light. In addition, in the blue subpixel BSP, the blue color filter 152c transmits blue light from light emitting element ED and emits the blue light outward, while absorbing wavelengths of green light and red light.

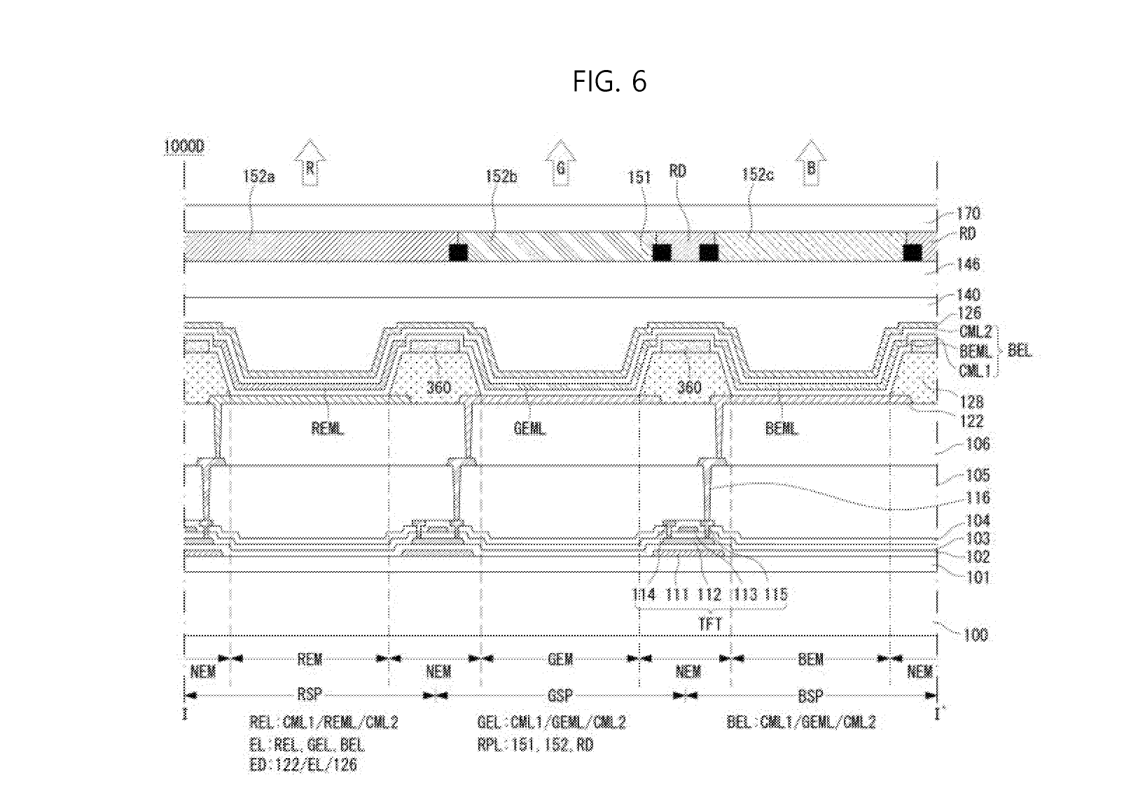

Here, the color filters 152 include the red color filter 152a, the green color filter 152b, and the blue color filter 152c corresponding to the red subpixel RSP, the green subpixel GSP, and the blue subpixel BSP. The red, green, and blue color filters 152a, 152b, and 152c may overlap the bank 128 located in the non-emission portions NEM, respectively, and among the color filters 152a, 152b, and 152c, the red color filter 152a may have the largest area overlapping the bank 128. This is because, as shown in FIGS. 2 and 6, the red color filter 152a extends outward from the red emission portion REM and is formed to extend farther outward than the boundary between the red subpixel RSP and the green or blue subpixel GSP or BSP. For example, the red color filter 152a is disposed across the boundaries with adjacent subpixels. Thereby, the light emitting display device according to the implementation of FIGS. 2 and 4 may increase transmissibility of red light among external light coming from the top through the extension of the red color filter 152a located outside the red emission portion REM, and the red external light having come into the red color filter 152a may be reflected by the surface of the reflective layer 160 and re-emitted, thereby being improving red reflection visibility.

The light emitting display devices of the implementations of the present disclosure may improve light transmittance without a polarizer, which reduces the light transmittance, using the color filters 152: 152a, 152b, and 152c and the light shielding layer 151 involved in color display as the anti-reflection structure RPL.

FIG. 4 shows an example of the light emitting display device 1000B having the plane arrangement of FIG. 2, in which the reflective layer 160 is formed directly in contact with the lower surface of the extension of the red color filter 152a or the lower surface of the dummy red color filter RD located in the non-emission portion NEM.

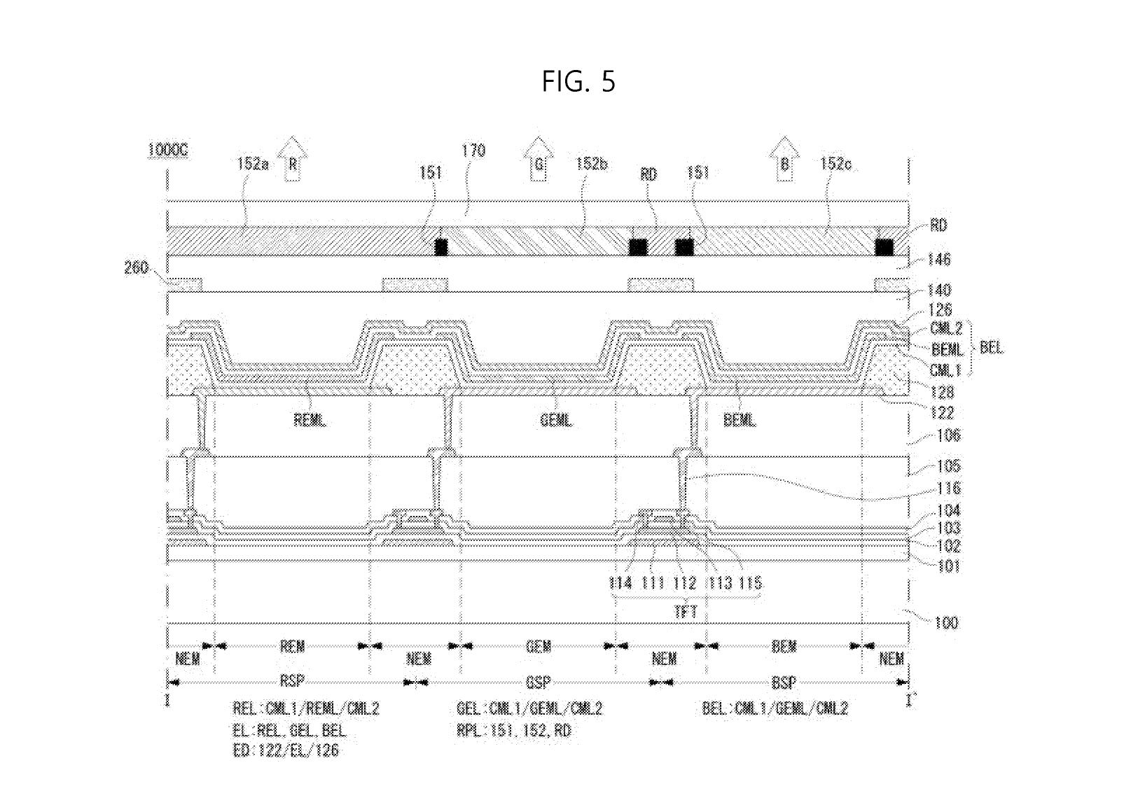

Further, the arrangement of the reflective layer 160 overlapping the extension of the red color filter 152a is not limited to the example of FIG. 4. In another implementation, as in FIG. 5, a reflective layer 260 may be located in direct contact with the encapsulation layer 140. Alternatively, in another implementation, as in FIG. 6, a reflective layer 360 may be located in direct contact with the upper surface of the bank 128.

For example, as shown in FIGS. 2 and 4 to 6, the light emitting display device according to one implementation of the present disclosure may have the reflective layer 160, 260, or 360 between the upper surface of the bank 128 and the color filters 152: 152a, 152b, and 152c, and the red color filter 152a that extends to overlap the reflective layer 160, 260, or 360, thereby increasing the reflection efficiency of light of some wavelengths among external light in the area where the red color filter 152a and the reflective layer 160, 260, or 360 overlap each other.

A common configuration in the light emitting display devices of FIGS. 4 to 6 according to the implementations of the present disclosure will be described.

The substrate 100 on which the respective subpixels RSP, GSP, and BSP are be formed as a single layer or a plurality of layers.

The substrate 100 may include at least one of a glass substrate, a plastic layer, or a metal plate having a constant supporting force. The substrate 100 may be formed of a flexible material. For example, when the substrate 100 is formed as a plurality of layers, the substrate 100 may have a stacked structure of a first organic layer, an inorganic insulating layer, and a second organic layer. The first organic layer on the outermost side may prevent the introduction of external impurities and have a protective function. The second organic layer may enable planarization of a surface on which an internal array structure is formed, and may prevent charge transfer or impurity transfer from the outside to the inside of the substrate 100. The inorganic insulating layer between the first and second organic layers may have a function of preventing moisture from being diffused between the first and second organic layers and conductive impurities from passing over to the second organic layer.

A first insulating layer 101 may be provided on the substrate 100. The first insulating layer 101 may function as a buffer layer or an active buffer layer. The buffer layer and the active buffer layer may serve to prevent impurities from being transferred upward from below wirings to an active layer 112 included in the internal array and support and protect components on the first insulating layer 101. The first insulating layer 101 may include a plurality of layers.

A thin film transistor TFT and a storage capacitor may be disposed for each of the subpixels RSP, GSP, and BSP on the first insulating layer 101.

A light-blocking layer 111 may be provided on the first insulating layer 101 to prevent light from being transferred to the active layer 112 of the thin film transistor TFT from below.

A second insulating layer 102 for insulation may be disposed between the light-blocking layer 111 and the active layer 112.

The thin film transistor TFT may be arranged on each of the plurality of subpixels on the second insulating layer 102. For example, the thin film transistor TFT may include the active layer 112, a gate electrode 113 overlapping the active layer 112 with a third insulating layer 103 interposed therebetween, and a first source/drain electrode 114 and a second source/drain electrode 115 connected to both sides of the active layer 112.

As an example, the storage capacitor may include a first storage electrode and a second storage electrode that overlap each other. At least one of the first storage electrode or the second storage electrode may include the same material as the active layer 112, and the other may include the same material as at least one of the gate electrode 113, the first and second source/drain electrodes 114 and 115, or the light-blocking layer 111.

The third insulating layer 103 between the active layer 112 and the gate electrode 113 may function as a gate insulating layer.

The active layer 112 may include, for example, a silicon-based or oxide semiconductor. The silicon-based semiconductor may include crystalline and/or amorphous silicon. The oxide semiconductor may include at least one of gallium oxide, tin oxide, zinc oxide, indium oxide, iron oxide, or indium-gallium-zinc oxide. In some cases, the oxide semiconductor layer may be formed as a plurality of layers having different materials or different material composition ratios. Each subpixel may include a plurality of thin film transistors, and the thin film transistors may be located on different layers. For example, each subpixel of the substrate 100 may include a plurality of thin film transistors having different active layers. For example, a first thin film transistor may have a silicon-based active layer (for example, a low-temperature polysilicon active layer) and be located closer to the substrate 100, and a second thin film transistor may have an oxide semiconductor-based active layer and be disposed on a layer above the first thin film transistor.

The active layer 112 may include a channel region overlapping the gate electrode 113, and source/drain regions connected to the first and second source/drain electrodes 114 and 115, respectively.

The third insulating layer 103 may be selectively disposed to correspond to the channel region of the active layer 112, or may be provided on the entire surface of the substrate 100 except for regions which the first and second source/drain electrodes 114 and 115 penetrate. The third insulating layer 103 may perform a function of insulating between the active layer 112 and the gate electrode 113. The third insulating layer 103 may be formed of an inorganic insulating material, and may include, for example, a silicon oxide (SiOₓ) layer, a silicon nitride (SiNₓ) layer, a silicon oxynitride (SiOₓN_{y}) layer, or a multilayer layer thereof.

The gate electrode 113 may be formed on the third insulating layer 103. The gate electrode 113 may be disposed to face the active layer 112 with the third insulating layer 103 interposed therebetween.

A fourth insulating layer 104 may be formed on the gate electrode 113 to cover the gate electrode 113 and protect the gate electrode 113. In addition, the fourth insulating layer 104 may perform a function of protecting at least one electrode of the thin film transistor TFT, for example, the gate electrode 113 and the active layer 112. The fourth insulating layer 104 may be formed of an inorganic insulating material. For example, the fourth insulating layer 104 may include, for example, a silicon oxide (SiOₓ) layer, a silicon nitride (SiNₓ) layer, a silicon oxynitride (SiOₓN_{y}) layer, or a multilayer layer thereof.

The first source/drain electrode 114 and the second source/drain electrode 115 may be disposed on the fourth insulating layer 104. The fourth insulating layer 104 and the third insulating layer 103 are provided with contact holes to allow the first and second source/drain electrodes 114 and 115 to come into contact with both ends of the active layer 112, respectively, by removing corresponding areas.

Each of the gate electrode 113 and the first and second source/drain electrodes 114 and 115 may be formed as a single layer or multiple layers.

When the gate electrode 113 and the first and second source/drain electrodes 114 and 115 are formed as a single layer, they may be formed of one selected from the group consisting of molybdenum (Mo), aluminum (Al), chromium (Cr), gold (Au), titanium (Ti), nickel (Ni), neodymium (Nd), copper (Cu), and alloys thereof. In addition, when the gate electrode 113 and the first and second source/drain electrodes 114 and 115 are formed as multiple layers, they may be formed as double layers of molybdenum/aluminum-neodymium, molybdenum/aluminum, titanium/aluminum, or copper/molytitanium. Alternatively, the gate electrode 113 and the first and second source/drain electrodes 114 and 115 may be formed as triple layers of molybdenum/aluminum-neodymium/molybdenum, molybdenum/aluminum/molybdenum, titanium/aluminum/titanium, or molytitanium/copper/molytitanium.

However, the gate electrode 113 and the first and second source/drain electrodes 114 and 115 are not limited thereto, and the gate electrode 113 and the first and second source/drain electrodes 114 and 115 may be formed as multiple layers formed of one selected from the group consisting of molybdenum (Mo), aluminum (Al), chromium (Cr), gold (Au), titanium (Ti), nickel (Ni), neodymium (Nd), copper (Cu), and alloys thereof.

Each of the first to fourth insulating layers 101, 102, 103, and 104 may be formed of an inorganic insulating layer. The inorganic insulating layer may be, for example, at least one of a silicon oxide layer, a silicon nitride layer, or a silicon oxynitride layer.

A first planarization layer 105 and a second planarization layer 106 may be provided on the first to fourth insulating layers 101, 102, 103, and 104. The first planarization layer 105 may be provided with a contact hole, and a connection electrode 116 connected to the second source/drain electrode 115 may be provided within the contact hole. The second planarization layer 106 is disposed to cover the connection electrode 116 and the first planarization layer 105. Each of the first and second planarization layers 105 and 106 may each include an organic material. The organic material may include one or more materials from among acrylic resins, phenolic resins, polyimide resins, unsaturated polyester resins, polyamide resins, benzocyclobutene, polyphenylene resins, and polyphenylene sulfide resins.

The connection electrode 116 may be formed as multiple layers, for example, formed of one selected from the group consisting of molybdenum (Mo), aluminum (Al), chromium (Cr), gold (Au), titanium (Ti), nickel (Ni), neodymium (Nd), copper (Cu), and alloys thereof. However, the implementations of the present disclosure are not limited thereto. In some cases, the connection electrode 116 may be omitted. If the connection electrode 116 is omitted, one of the first and second source/drain electrodes 114 and 115 may be directly connected to the first electrode 122 of the light emitting element ED.

The light emitting element ED is formed by stacking the first electrode 122, an intermediate layer EL, and the second electrode 126.

The first electrode 122 may function as an anode. The first electrode 122 may pass through the second planarization layer 106 and the first planarization layer 105 and be connected to the transistor TFT. The illustrated example shows a case in which the connection electrode 116 is further provided between the first electrode 122 and the transistor TFT, the transistor TFT and the connection electrode 116 are connected, and the connection electrode 116 and the first electrode 122 are connected, but the second source/drain electrode 115 of the transistor TFT and the first electrode 122 of the light emitting element ED may be directly connected without the connection electrode 116.

The first electrode 122 may include a metal material having high reflectivity. For example, the first electrode 122 may be formed as a multilayer structure, such as a stacked structure (Ti/Al/Ti) of aluminum (Al) and titanium (Ti), a stacked structure (ITO/Al/ITO) of aluminum (Al) and ITO, an Ag/Pd/Cu (APC) alloy, a stacked structure (ITO/APC/ITO) of an APC alloy and ITO, or a stacked structure (Ag/MoTI) of silver (Ag) and a molybdenum/titanium alloy, or may include a single layer structure formed of one material selected from silver (Ag), aluminum (Al), molybdenum (Mo), gold (Au), magnesium (Mg), calcium (Ca), and barium (Ba), or an alloy of two or more materials selected therefrom. The first electrode 122 may be referred to as a reflective electrode.

The intermediate layer EL is provided on the first electrode 122. The intermediate layer EL may include a first common layer CML1 related to holes, such as a hole injection layer or a hole transport layer, an organic emission layer EML, and a second common layer CML2 related to electrons, such as an electron transport layer or an electron injection layer. As shown in FIGS. 4 to 6, the organic emission layer EML may include a red emission layer REML in the red subpixel RSP, a green emission layer GEML in the green subpixel GSP, and a blue emission layer BEML in the blue subpixel BSP. For example, as shown in FIGS. 4 to 6, the red emission layer REML may be patterned in the red subpixel RSP, the green emission layer GEML may be patterned in the green subpixel GSP, and the blue emission layer BEML may be patterned in the blue subpixel BSP. However, this arrangement is only an example. The intermediate layer EL, which is provided as a red stack REL, a green stack GEL, or a blue stack BEL, may be provided in a corresponding one of the subpixels RSP, GSP, and BSP. The light emitting element ED of each subpixel RSP, GSP, or BSP may have a plurality of stacks formed as the intermediate layer EL by stacking the first common layer CML1, a corresponding color emission layer REML, GEML, or BEML, and the second common layer CML2 between the first and second electrodes 122 and 126, and a charge generation layer may be included between adjacent stacks. In some cases, the intermediate layer EL may be provided in the same tandem structure including a plurality of stacks in the respective subpixels RSP, GSP, and BSP. The tandem structure includes a charge generation layer between the plurality of stacks, and each stack may include one or more emission layers. When the intermediate layer EL has the same structure for the respective subpixels RSP, GSP, and BSP, the light emitting elements ED may emit white light, and each of the red, green, and blue color filters 152a, 152b, and 152c of the anti-reflection structure RPL may selectively emit light of a color corresponding to each subpixel.

The edge of the first electrode 122 of each subpixel RSP, GSP, or BSP may overlap the bank 128. The area of the first electrode 122 exposed from the bank 128 may define the emission portion REM, GEM, or BEM. The bank 128 opens the emission portion REM, GEM, or BEM of each subpixel RSP, GSP, or BSP. The bank 128 may include an organic or inorganic insulating material.

When a voltage is applied to the first electrode 122 and the second electrode 126, holes and electrons move to the organic emission layer through the hole injection layer and the hole transport layer and the electron injection layer and the electron transport layer, respectively, and the holes and the electrons combine with each other in the organic emission layer to form excitons, and the excitons fall from the excited state to the ground state, thereby emitting light.

A plurality of layers or at least one layer, included in the intermediate layer EL: REL, GEL, or BEL may be provided in common in the entire active area AA.

The second electrode 126 may be a common layer that is disposed in common in the subpixels SP and applies the same voltage. For this purpose, the second electrode 126 may be disposed to extend from the active area AA to a part of the non-active area NA.

The second electrode 126 may be a transmissive electrode. The second electrode 126 may include a transparent metal material (e.g., a transparent conductive material (TCO)), such as indium tin oxide (ITO) or indium zinc oxide (IZO) that may transmit light, or a semi-transmissive metal material (e.g., a semi-transmissive conductive Material), such as magnesium (Mg), silver (Ag), or an alloy of magnesium (Mg) and silver (Ag). When the second electrode 126 includes a semi-transmissive conductive material, luminance efficiency may be increased by microcavities. When the second electrode 126 includes a semi-transmissive conductive material, the thickness of the second electrode 126 may be thin enough to transmit light.

The first electrode 122 may include a reflective electrode to prevent light generated in the intermediate layer EL from being transmitted to light shielding components below the first electrode 122. The light generated from the intermediate layer EL resonates between the second electrode 126 and the first electrode 122, and may be finally emitted upward through the second electrode 126. Since the first electrode 122 includes a reflective component, even if the first electrode 122 overlaps the wirings and the transistors TFT, the light emitted from the light emitting elements ED may be recognized in the emission portions REM, GEM, and BEM without being affected by the arrangement between the first electrode 122, and the wirings and the transistors TFT.

The light emitting display devices of the implementations of the present disclosure are implemented in a top emission type in which light is emitted upward. In this case, the first electrode 122 includes a reflective electrode, and the light generated from the intermediate layer EL resonates through reflection and re-reflection between the first electrode 122 and the second electrode 126, and is finally emitted toward the second electrode 126.

The encapsulation layer 140 that protects the light emitting element ED may be further provided on the second electrode 126. The encapsulation layer 140 may be a single layer or multiple layers. If the encapsulation layer 140 is formed as multiple layers, the encapsulation layer 140 may be formed by stacking at least one inorganic encapsulation layer and at least one organic encapsulation layer. The inorganic encapsulation layer may prevent moisture penetration, and the organic encapsulation layer may cover particles and perform a function of planarizing a surface. On a plane, the organic encapsulation layer may be located inside the inorganic encapsulation layer. In this case, the inorganic encapsulation layer may prevent moisture penetration through the side.

A protective layer 146 may be provided on the encapsulation layer 140. The protective layer 146 may perform a function of planarizing a surface on which the anti-reflection structure RPL is formed. The protective layer 146 may be a transparent organic layer.

In some cases, the protective layer 146 may be omitted, and the light shielding layer 151, the color filters 152: 152a, 152b, and 152c, and the dummy red color filter RD may be directly provided on the encapsulation layer 140.

In addition, a touch sensor may be provided in place of the protective layer 146. The touch sensor may include a touch buffer layer, a bridge layer, a touch insulating layer, a touch sensor layer, and a touch protective layer, and the light shielding layer 151 and the color filters 152: 152a, 152b, and 152c, and the dummy red color filter RD may be disposed on the touch protective layer located at the uppermost part of the touch sensor. When the touch sensor is provided between the encapsulation layer 140, and the light shielding layer 151 and the color filters 152, at least one of electrodes (e.g., the bridge layer and touch sensor layer) within the touch sensor may be used as a reflective layer 260 according to the implementation of FIG. 5.

The light emitting display device 1000 according to the first implementation of the present disclosure according to FIG. 2 has a structure in which the red color filter 152a and the dummy red color filter RD are separated. In addition, the reflective layer 160 is provided to overlap the red color filter 152a and the dummy red color filter RD that are separated. The red color filter 152a and the reflective layer 160 overlap in the non-emission portion NEM outside the emission portion REM of the red subpixel RSP, red light among incident external light passes through the red color filter 152a and is reflected by the reflective layer 160, and thereby, reflectance of the red external light may be increased. Similarly, the overlapping structure of the dummy red color filter RD and the reflective layer 160 may increase reflectance of the red external light reflectance around the green color filter 152b and the blue color filter 152c.

A cover layer 170 is disposed on the anti-reflection structure RPL including the light shielding layer 151, the color filters 152, and the dummy red color filter RD to protect the components disposed under the cover layer 170 from external moisture or physical stimulation. It is to be noted that the cross-sectional structures of the display device shown in FIGS. 4-6 are only provided by way of example only, and other various structures of the display device are also possible. Thus, one or more layers or components as well as the relative arrangements of the components or layers of the display device may be variously changed when necessary.

In addition, although it is shown by way of example that the light emitting display device is an organic light emitting display device, but the present disclosure is not limited thereto, and other types of light emitting display device such as Micro-LED display device or quantum dot light emitting display device are also possible.

Comparative Example EX1 of FIG. 7 indicates a structure in which red, green, and blue color filters are arranged to have similar areas without a reflective layer and a dummy red color filter. Experimental Example EX2 of FIG. 7 indicates a structure in which, like FIG. 2, a red color filter extends to an adjacent non-emission portion and a dummy red color filter RD and a reflective layer 160 are provided.

Therefore, while the structure of the light emitting display device of Comparative Example EX1 in which the red, green, and blue color filters are arranged to have similar areas in the non-emission portions NEM exhibits initial black with a color tone shifted to cyan (cyanish), the light emitting display device according to one implementation EX2 of the present disclosure may implement initial black without being biased to a specific color by increasing reflection efficiency of light in the direction of red, which is optically complementary to cyan. In addition, while the structure of the light emitting display device in which the red, green, and blue color filters are arranged to have similar areas in the non-emission portions implements white with a color tone shifted to cyan, the light emitting display device according to one implementation of the present disclosure may increase the purity of white when driven to implement white by increasing the reflection efficiency of red that is optically complementary to cyan. Therefore, the light emitting display device according to one implementation of the present disclosure may improve the color temperature of white when driven. In addition, the light emitting display device according to one implementation of the present disclosure may improve an initial color tone or a color tone when implementing white through the overlapping relationship between the red color filter 152a or the dummy red color filter RD and the reflective layer 160 in the non-emission portion without changing the area of the emission portion, thereby being capable of preventing the deterioration of a lifespan balance among red, green, and blue subpixels caused by the change in the area of the emission portion. Although in the case of the light emitting display device of Comparative Example EX1, it is described as exhibiting initial black with a color tone shifted to cyan (cyanish), but the present disclosure is not limited thereto, and thus the light emitting display device of the present disclosure may be adaptively adjusted to complement the color shift or derivation by increasing the reflection efficiency of any one of red, green and blue.

According to the second implementation of the present disclosure shown in FIG. 3, a light emitting display device 1000A has a structure in which a red color filter 152a extends to non-emission portions NEM of a green subpixel GSP and a blue subpixel BSP and is connected to a dummy red color filter RD. In addition, a reflective layer 160 is continuously formed in the subpixels RSP, GSP, and BSP depending on the connection shape of the red color filter 152a and the dummy red color filter RD. In the subpixels RSP, GSP, and BSP, the reflective layer 160 has a shape that surrounds each emission portion REM, GEM, or BEM and may be continuously formed in adjacent subpixels. For example, in this case, the reflective layer 160 may be integrally provided on the substrate 100 and have a shape that has openings for the respective emission portions REM, GEM, and BEM. Here, the size of the opening of the reflective layer 160 corresponding to the red emission portion REM may be smaller than the sizes of the openings corresponding to the green emission portion GEM and the blue emission portion BEM. The reason for this is to prevent the reflective layer 160 from overlapping the green color filter 152b and the blue color filter 152c located in the non-emission portions NEM, because the green color filter 152b and the blue color filter 152c are disposed in the green emission portion GEM and the blue emission portion BEM and also extend from the outer lines of the corresponding emission portions to parts of the corresponding non-emission portions NEM for sufficient color reproduction in the corresponding emission portions. Here, each of the green color filter 152b provided in the green subpixel GSP and the blue color filter 152c provided in the blue subpixel BSP may be island-shaped. The dummy red color filter RD is disposed between the green color filter 152b and the blue color filter 152c that are spaced apart from each other.

The red color filter 152a and the dummy red color filter RD may be formed of the same material.

The light emitting display device 1000A according to the second implementation shown in FIG. 3 has an increased overlapping area between the reflective layer 160, and the red color filter 152a and the dummy red color filter RD compared to the structure of FIG. 2, thereby being capable of further increasing red reflection efficiency for external light and more effectively preventing occurrence of a cyanish shift in the initial black or white state.

The light emitting display device 1000A according to the second implementation shown in FIG. 3 differs from the light emitting display device 1000 of the implementation shown in FIG. 2 described above in that the red color filter 152a disposed in the non-emission portion NEM of the red subpixel RSP and the dummy red color filter RD disposed in the non-emission portions NEM of the green subpixel GSP and the blue subpixel BSP extend to be connected to each other.

In this case, the reflective layer 160 of the light emitting display device 1000A according to the second implementation may have a shape that is continuously formed in the entire active area AA. In addition, the openings of the reflective layer 160 expose at least the emission portions REM, GEM, and BEM. The light emitting display device 1000A according to the second implementation may be configured in such a way that most of the non-emission portions NEM are used as areas that improve external light reflection efficiency, thereby having a superior effect of increasing red reflection efficiency to that of the first implementation.

FIGS. 4 to 6 illustrate that the light emitting display devices of various implementations of the present disclosure have a vertical position difference of the reflective layer.

Further, the light emitting display devices 1000B, 1000C, and 1000D according to the implementations shown in FIGS. 4 to 6 may follow the planar positional relationship among the red, green, and blue color filters 152a, 152b, and 152c, the dummy red color filter RD, and the reflective layer 160 of FIGS. 2 or 3.

When the light emitting element ED provided in each subpixel has a stacked configuration of the first electrode 122, the intermediate layer EL, and the second electrode 126, the intermediate layer EL may be located on the bank 128 on which the reflective layer 160 is formed.

As shown in FIG. 4, the light emitting display device 1000B according to one implementation of the present disclosure may have the reflective layer 160 provided under the red color filter 152a and the dummy red color filter RD. In this case, the reflective layer 160 may be disposed in contact with the lower surfaces of the red color filter 152a and the dummy red color filter RD.

As shown in FIG. 5, the light emitting display device 1000C according to one implementation of the present disclosure may have the reflective layer 260 provided on the encapsulation layer 140. In this case, the reflective layer 260 may be located on the uppermost surface of the encapsulation layer 140. However, the light emitting display device 1000C according to one implementation of the present disclosure is not limited thereto. For example, when the encapsulation layer 140 is formed as a plurality of layers, the reflective layer 260 may be located on any one of the plurality of layers.

In addition, as shown in FIG. 6, the light emitting display device 1000D according to one implementation of the present disclosure may have the reflective layer 360 provided on the uppermost surface of the bank 128. In this case, the uppermost surface of the bank 128 and the lower surface of the reflective layer 360 may be in direct contact. In the implementation of FIG. 6, the reflective layer 360 may be formed immediately after formation of the bank 128.

When the light emitting element ED provided in each subpixel has a stacked configuration of the first electrode 122, the intermediate layer EL, and the second electrode 126, the intermediate layer EL may be located on the upper portion of the bank 128 on which the reflective layer 160 is formed.

Among structures having an anti-reflection structure including color filters and a light shielding layer, a structure having emission portions of respective subpixels, in the same manner as a light emitting display device employing a polarizer, and employing color filters overlapping the non-emission portions of the corresponding subpixels with the same width has good transmittance, but a color tone shifted in the direction of cyan may be observed when expressing white.

The light emitting display devices according to implementations of the present disclosure aim to secure transmittance compared to the light emitting display device employing the polarizer, and at the same time, acquire an initial stable black visibility effect, which may be obtained through the light emitting display device employing the polarizer, and the lifespan balance among red, green, and blue subpixels even over time.

In order to improve the color tone of red, a method of increasing the size of the emission portion of the red subpixel may be considered, but in this case, a difference in lifespan between the emission portion of the increased subpixel and the emission portions of the subpixels having a normal size occurs, and the balance in expressing white deteriorates over time, and accordingly, a color temperature tends to decrease.

The light emitting display device of the present disclosure does not increase the emission portion of the red subpixel, but additionally provides an extension of the red color filter 152a or the dummy color filter RD in an area used as the non-emission portion on the substrate, and provides the reflective layer 160 overlapping the extension of the red color filter 152a or the dummy color filter RD, so that red light among external light is re-reflected to increase the color tone of the red external light in the initial state or when implementing white, and shifts the color tone changed in the direction of cyan to the initial black state or the white state when driven.

In the light emitting display device of FIGS. 2 or 3, the respective emission portions of the red, green, and blue subpixels are illustrated as having the same size. However, the light emitting display device according to the implementation of the present disclosure is not limited thereto. The sizes of the respective emission portions of the red, green, and blue subpixels may be adjusted in consideration of the efficiency of the light emitting element provided in each subpixel and the proportion to white.

As an example in which the sizes of the emission portions of red, green, and blue subpixels are different, if efficiency of blue by a light emitting element is lower than efficiency of red and green, the emission portion of the blue subpixel may be set to be larger than the emission portions of the red subpixel and the green subpixel. In addition, if a contribution to light emission of green is high by expressing white, the area of the emission portion of the green subpixel can be set to be larger than the area of the emission portion of the red subpixel. Here, in the light emitting display devices according to the implementations of the present disclosure, even if the area of the emission portion REM of the red subpixel RSP is set to be larger than the areas of the emission portions GEM and BEM of the green and blue subpixels GSP and BSP, the red color filter 152a may have a larger overlapping area with the reflective layer 160 in the non-emission portion NEM than those of the green color filter 152b and the blue color filter 152c, and allow red light among external light entering from the outside to be incident and returned upward by the reflective layer 160 to increase an amount of red reflection.

The reflective layer 160 may be located at least below the red color filter 152a so that external light incident from the outside passes through the red color filter 152a and then is incident on the reflective layer 160. The reflective layer 160 may include, for example, a reflective metal. When the external light enters the reflective layer 160 through the red color filter 152a, red light that has passed through the red color filter 152a is reflected from the upper surface of the reflective layer 160 and emitted again to the outside.

In the light emitting display devices according to the implementations of the present disclosure, the reflective layer 160 may overlap the red color filter 152a overlapping the non-emission portion NEM with a larger area than the green and blue color filters 152b and 152c, so that external light having red wavelengths transmitted through the red color filter 152a from above outside the light emitting display device may be reflected upward by the reflective layer 160.

Further, as shown in FIGS. 2 to 6, the light emitting display devices according to the implementations of the present disclosure may further include the dummy red color filter RD in at least one of the non-emission portion NEM of the green subpixel GSP or the non-emission portion NEM of the blue subpixel BSP in addition to the red color filter 152a extending to the non-emission portion NEM of the red subpixel RSP. In addition, the dummy red color filter RD overlaps the reflective layer 160 so that the external light of the red wavelengths transmitted through the dummy red color filter RD from above may be reflected upward by the reflective layer 160.

Further, the above-described implementation is to solve a shift to cyan in the initial black state or when driven to implement white in the structure in which the red, green, and blue color filters overlap adjacent non-emission portions with similar areas. However, the light emitting display devices of the implementations of the present disclosure are not limited thereto. When light coming from the configuration below the anti-reflection structure in the initial state is biased to a specific color, the dummy color filter that is complementary to the color may be disposed to overlap the reflective layer. When the reflective layer has a vertical position between the color filters and the upper surface of the bank, the reflection visibility of the wavelengths of light transmitted by the dummy color filter may be improved due to reflection of external light by the reflective layer.

The light emitting display devices of the implementations of FIGS. 2 to 6 have described an example in which subpixels are arranged in the form of RGB stripes.

In another implementation, an example in which subpixels are arranged in the form of RGBG will be described.

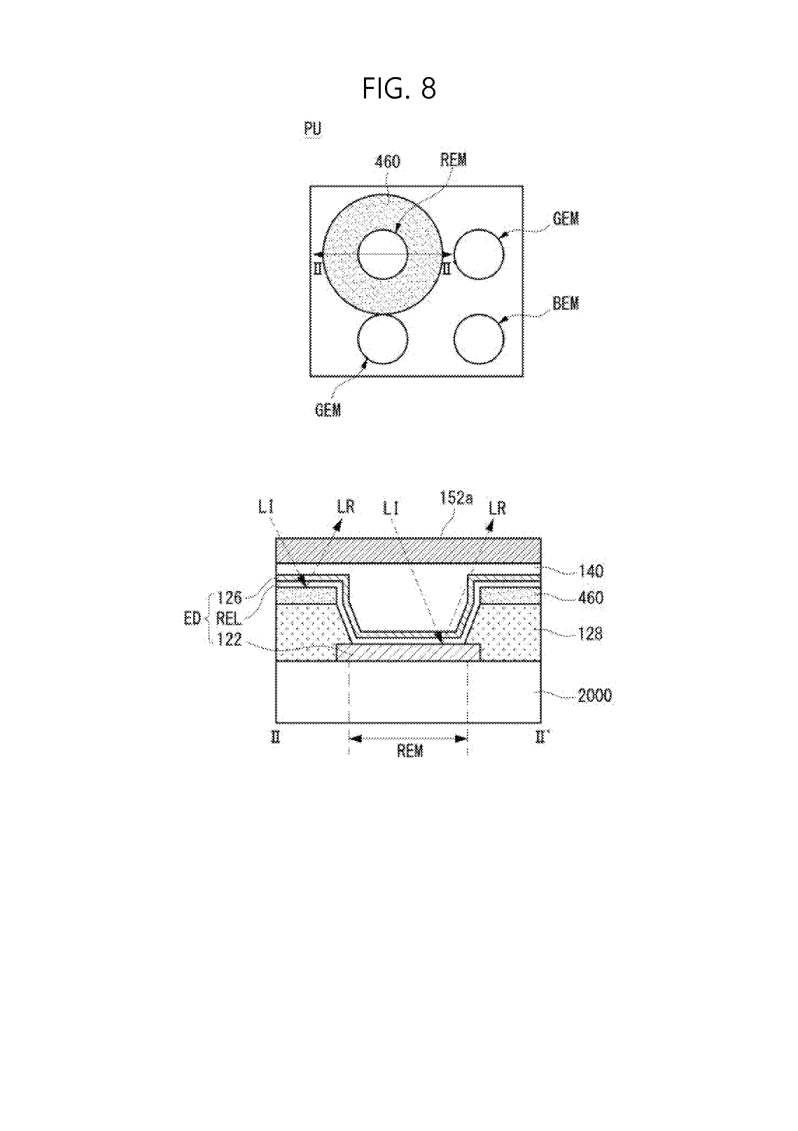

FIG. 8 is a view showing a light emitting display device according to another implementation (for example, a third implementation) of the present disclosure.

As shown in FIG. 8, the light emitting display device according to the third implementation of the present disclosure has a red emission portion REM and a green emission portion GEM arranged in a first row and a green emission portion GEM and a blue emission portion BEM arranged in a second row in one unit pixel PU. Emission portions REM, GEM, and BEM are disposed on a substrate 2000. The substrate 2000 comprises a thin film transistor array and at least one planarization layer to cover the thin film transistor array. Such unit pixels are repeatedly arranged in the active area AA (see FIG. 1).

An example in which the green emission portion GEM with a high contribution to luminance when expressing white is arranged to have a relatively large area is shown.

The light emitting display device according to the third implementation of the present disclosure shows an example where a reflective layer 460 is disposed in a form surrounding the red emission portion REM.

In this case, a red color filter 152a is disposed to extend to overlap not only the red emission portion REM but also the entirety of an area in which the reflective layer 460 is formed. In this case, the red color filter 152a may overlap the bank 128. FIG. 8 shows an example in which the reflective layer 460 is located on the upper surface of the bank 128, as in the above-described implementation of FIG. 6, but the implementations of the present disclosure are not limited thereto. For example, the reflective layer 460 may be disposed on an encapsulation layer 140, as in FIG. 5, or may be disposed on the lower surface of the red color filter 152a.

As shown in FIG. 8, light LI incident from the outside through the red color filter 152a is reflected from the upper surface of the reflective layer 460, and thus, reflected light, which is red light, LR is emitted. In addition, among the light LI incident through the red color filter 152a, light toward the upper surface of a first electrode 122 is reflected by the reflective layer 460, and thus, reflected light, which is red light, LR is emitted through the red color filter 152a. Here, as the light LI incident from the outside passes through the red color filter 152a, the red color filter 152a absorbs light of other colors excluding red light and transmits only red light. Therefore, referring to FIG. 8, it may be confirmed that the reflection efficiency of red light among external light is improved in the light emitting display device according to the third implementation of the present disclosure.

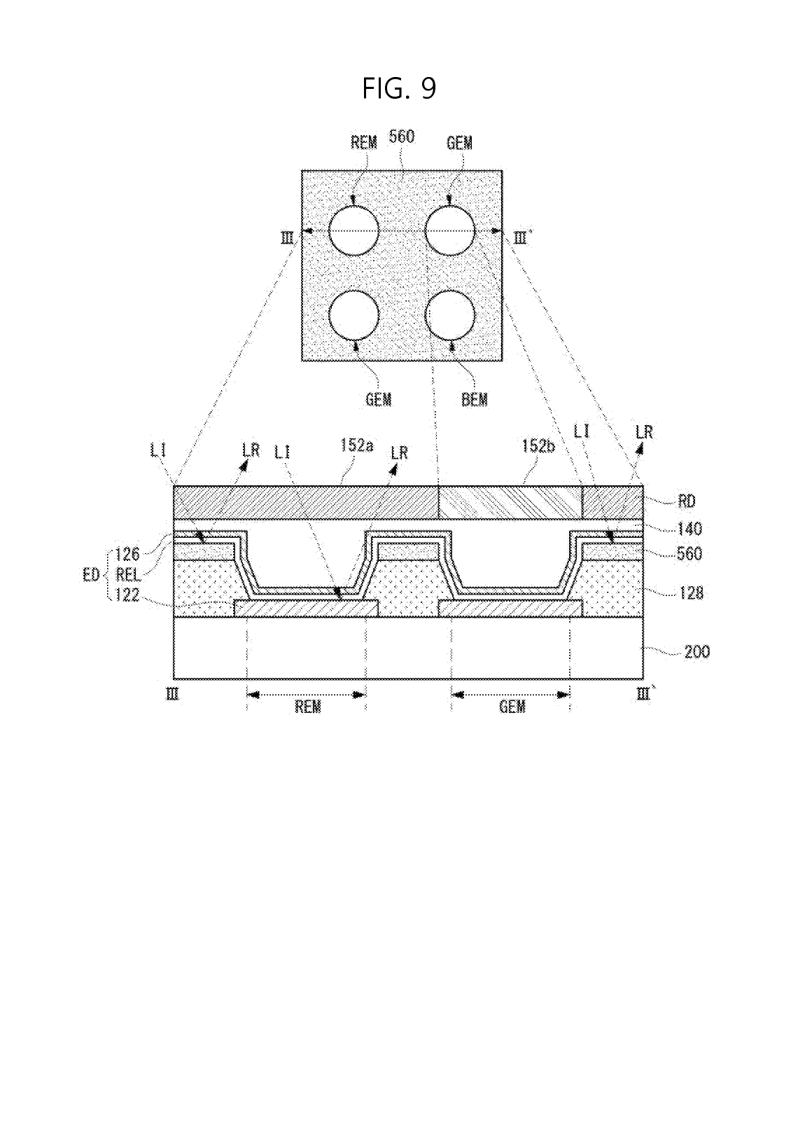

FIG. 9 is a view showing a light emitting display device according to yet another implementation (for example, a fourth implementation) of the present disclosure.

The arrangement of emission portions REM, GEM, and BEM of the light emitting display device according to the fourth implementation of the present disclosure shown in FIG. 9 is the same as that of the above-described third implementation. Emission portions REM, GEM, and BEM are arranged on a substrate 200.

Unlike the third implementation, in the fourth implementation, a reflective layer 560 is continuously formed to be disposed in non-emission portions excluding the emission portions REM, GEM, and BEM. A cross-sectional view shown in FIG. 9 illustrates an example in which the reflective layer 560is located on the upper surface of the bank 128, but the implementations of the present disclosure are not limited thereto. As in FIG. 4, the reflective layer 560 may be located at any position within the vertical space between the upper surface of the bank 128 and the red color filter 152a or the dummy red color filter RD.

The bank 128 may have a form in which the side surface between the upper surface and the lower surface of the bank 128 is inclined at an acute angle with the lower surface of the bank 128. In this case, the upper surface of the bank 128 may have a smaller width or diameter than the lower surface of the bank 128. Therefore, when the reflective layer 560 is disposed in contact with the upper surface of the bank 128, an area in which the reflective layer 560 is formed may be relatively small. However, the reflective layer 560 may be located on the encapsulation layer 140 (see FIG. 4) or the protective layer 146 (see FIG. 5) so that the width or diameter of the reflective layer 560 may be increased.

Further, in the fourth implementation, a red color filter 152a located in the non-emission portion NEM outside the red emission portion REM may be connected to a dummy red color filter RD located in the non-emission portions NEM outside the green emission portion GEM and the blue emission portion BEM.

As shown in FIG. 9, light LI incident from the outside through the red color filter 152a is reflected from the upper surface of the reflective layer 560, and thus, reflected light, which is red light, LR is emitted. In addition, among the light LI incident through the red color filter 152a, light toward the upper surface of a first electrode 122 is reflected by the reflective layer 560, and thus, reflected light, which is red light, LR is emitted through the red color filter 152a. Here, as the light LI incident from the outside passes through the red color filter 152a, the red color filter 152a absorbs light of other colors excluding red light and transmits only red light. Therefore, referring to FIG. 9, it may be confirmed that the reflection efficiency of red light among external light is improved in the light emitting display device according to the fourth implementation of the present disclosure.

As is apparent from the above description, a light emitting display device of the present disclosure has the following effects.

The light emitting display device according to one implementation of the present disclosure may have an anti-reflection structure including color filters and a light shielding layer involved in color display, thereby being capable of improving light transmittance without a polarizer.

The light emitting display device according to one implementation of the present disclosure may have a reflective layer disposed between the upper surface of a bank and the color filters, and extend the color filter overlapping the reflective layer, thereby being capable of increasing the reflection efficiency of light having a specific wavelength range among external light in an area in which the color filter and the reflective layer overlap.

The light emitting display device according to one implementation of the present disclosure may employ a reflection efficiency structure of a complementary color by overlapping the reflective layer and the color filter, even if emitted light is biased to a specific color under the anti-reflection structure, thereby being capable of implementing clear colors without a decrease in visibility observed as the specific color when finally emitting light. For example, the initial black state may be implemented as clear black, and when the light emitting display device is driven to display colors including white, a corresponding color may be implemented without being biased to a specific color. Therefore, a high contrast ratio can be obtained.

The light emitting display device according to one implementation of the present disclosure may control visibility adjustment by controlling the color filters of the anti-reflection structure and the reflective layer without adjusting the areas of emission portions, thereby being capable of preventing a decrease in the lifespan balance among red, green, and blue subpixels that occurs when increasing the area of the emission portion of a specific color, and maintaining color temperature characteristics.

A light emitting display device according to one implementation of the present disclosure may comprise a substrate comprising a red subpixel, a green subpixel, and a blue subpixel, each having an emission portion and a non-emission portion, a bank at the non-emission portions of the red subpixel, the green subpixel, and the blue subpixel, a light emitting element at each of the red subpixel, the green subpixel, and the blue subpixel, an encapsulation layer to cover the light emitting element, a color filter located on the encapsulation layer and to overlap the emission portions of the red subpixel, the green subpixel, and the blue subpixel and a reflective layer located between the bank and the color filter and to overlap at least the bank.

In a light emitting display device according to one implementation of the present disclosure, the color filter may comprise a red color filter to overlap the emission portion of the red subpixel, a green color filter to overlap the emission portion of the green subpixel, and a blue color filter to overlap the emission portion of the blue subpixel. The red color filter may have an extension to extend to the non-emission portion outside the emission portion of the red subpixel, and the extension of the red color filter is provided across a boundary between the red subpixel and the green subpixel or the blue subpixel adjacent to the red subpixel.

In a light emitting display device according to one implementation of the present disclosure, the color filter may comprise a red color filter, a green color filter, and a blue color filter corresponding to the red subpixel, the green subpixel, and the blue subpixel. Among overlapping areas of the red color filter, the green color filter, and the blue color filter with the bank, the overlapping area of the red color filter with the bank may be largest.

A light emitting display device according to one implementation of the present disclosure may further comprise a dummy red color filter to overlap at least one of the non-emission portion of the green subpixel or the non-emission portion of the blue subpixel.

In a light emitting display device according to one implementation of the present disclosure, the red color filter may comprise a first region overlapping the emission portion of the red subpixel and a second region overlapping the non-emission portion of the red subpixel, the first region and the second region are connected to each other, and the second region has a shape to surround the first region. The second region may be connected to the dummy red color filter.

In a light emitting display device according to one implementation of the present disclosure, the reflective layer may overlap the red color filter at the non-emission portion of the red subpixel and the dummy red color filter, respectively.

In a light emitting display device according to one implementation of the present disclosure, the reflective layer may be in contact with an upper surface of the bank.

In a light emitting display device according to one implementation of the present disclosure, the reflective layer may be in contact with an upper surface of the encapsulation layer.

In a light emitting display device according to one implementation of the present disclosure, the reflective layer may be located in contact with a lower surface of the color filter.

In a light emitting display device according to one implementation of the present disclosure, it may further include a light shielding layer located on the encapsulation layer and overlapping the non-emission portion, and the light shielding layer may overlap at least a portion of the bank.

In a light emitting display device according to one implementation of the present disclosure, the reflective layer may comprise a reflective metal.

In a light emitting display device according to one implementation of the present disclosure, the light emitting element may comprise a first electrode and a second electrode facing each other, and an intermediate layer between the first electrode and the second electrode. The reflective layer may be electrically separated from each of the first electrode and the second electrode.

In a light emitting display device according to one implementation of the present disclosure, the intermediate layer may comprise an emission layer, a first common layer under the emission layer, and a second common layer above the emission layer. The reflective layer may be in contact with or overlaps the first common layer or the second common layer.

In a light emitting display device according to one implementation of the present disclosure, the bank may comprise a black material.

In a light emitting display device according to one implementation of the present disclosure, an edge of the first electrode located at the non-emission portion may be covered by the bank.

A light emitting display device according to one implementation of the present disclosure may comprise a substrate comprising a first subpixel, a second subpixel and a third subpixel, each having an emission portion and a non-emission portion, a bank provided at the non-emission portions of the first to third subpixels, a light emitting element provided at each of the first to third subpixels, an encapsulation layer to cover the light emitting element, a color filter located on the encapsulation layer and to overlap the emission portion and a reflective layer located between the bank and the color filter and to reflect external light having passed through the color filter toward the color filter.

In a light emitting display device according to one implementation of the present disclosure, the color filter may comprise a first color filter, a second color filter, and a third color filter corresponding to the first to third subpixels, respectively.

A light emitting display device according to one implementation of the present disclosure may further comprise a dummy color filter to transmit light of a same color as the first color filter at an area of the non-emission portion overlapping the reflective layer.

In a light emitting display device according to one implementation of the present disclosure, the dummy color filter may be positioned at a same layer as the first to third color filters.

In a light emitting display device according to one implementation of the present disclosure, the first color filter may have a larger overlapping area with the non-emission portion than each of the second color filter and the third color filter.

In a light emitting display device according to one implementation of the present disclosure, light directed from below the color filter toward the color filter in an initial state may have wavelengths to be optically complementary to wavelengths of light configured to pass through the first color filter.

In a light emitting display device according to one implementation of the present disclosure, the first color filter and the dummy color filter may transmit light having wavelengths of 600 nm to 650 nm. The second color filter may transmit light having wavelengths of 510 nm to 590 nm. The third color filter may transmit light having wavelengths of 430 nm to 495 nm.

A light emitting display device according to one implementation of the present disclosure may comprise a substrate comprising a first subpixel, a second subpixel and a third subpixel, each having an emission portion and a non-emission portion; a light emitting element provided at each of the first to third subpixels; a color filter located over the light emitting element and disposed to overlap the emission portions of the first to third subpixels; and a reflective layer disposed within the non-emission portions of the first to third subpixels and having openings exposing the emission portions of the first to third subpixels.

The light emitting display device according to one implementation of the present disclosure may have an anti-reflection structure including color filters and a light shielding layer involved in color display, thereby being capable of improving light transmittance without a polarizer.

The light emitting display device according to one implementation of the present disclosure may have a reflective layer disposed between the upper surface of a bank and the color filters, and extend the color filter overlapping the reflective layer, thereby being capable of increasing the reflection efficiency of light having a specific wavelength range among external light in an area in which the color filter and the reflective layer overlap.

The light emitting display device according to one implementation of the present disclosure may employ a reflection efficiency structure of a complementary color by overlapping the reflective layer and the color filter, even if emitted light is biased to a specific color under the anti-reflection structure, thereby being capable of implementing clear colors without a decrease in visibility observed as the specific color when finally emitting light. For example, the initial black state may be implemented as clear black, and when the light emitting display device is driven to display colors including white, a corresponding color may be implemented without being biased to a specific color. Therefore, a high contrast ratio can be obtained.

The light emitting display device according to one implementation of the present disclosure may control visibility adjustment by controlling the color filters of the anti-reflection structure and the reflective layer without adjusting the areas of emission portions, thereby being capable of preventing a decrease in the lifespan balance among red, green, and blue subpixels that occurs when increasing the area of the emission portion of a specific color, and maintaining color temperature characteristics.

By adjusting a color filter and adding a reflection layer, the light emitting device according to one implementation of the present disclosure may prevent a specific color from being visually recognized in an initial state or after driving over a certain time, achieve a high efficiency, and minimize increase in material costs, thereby being capable of exhibiting environmental, social, and governance (ESG) effects.

Through the above description, it should be apparent to those skilled in the art that various changes and modifications are possible without departing from the technical spirit of the present disclosure. Therefore, the technical scope of the present disclosure should not be limited to the above detailed description, but should be defined by the scope of the claims.

What is claimed is:

1. A light emitting display device comprising:
a substrate comprising a red subpixel, a green subpixel, and a blue subpixel, each having an emission portion and a non-emission portion;
a bank at the non-emission portion of each of the red subpixel, the green subpixel, and the blue subpixel;
a light emitting element at each of the red subpixel, the green subpixel, and the blue subpixel;
an encapsulation layer covering the light emitting element of each of the red subpixel, the green subpixel, and the blue subpixel;
a color filter located on the encapsulation layer and overlapping the emission portion of each of the red subpixel, the green subpixel, and the blue subpixel; and
a reflective layer located between the bank and the color filter and overlapping at least the bank.

2. The light emitting display device according to claim 1, wherein:
the color filter comprises a red color filter overlapping the emission portion of the red subpixel, a green color filter overlapping the emission portion of the green subpixel, and a blue color filter overlapping the emission portion of the blue subpixel, and
the red color filter has an extension that extends to the non-emission portion outside the emission portion of the red subpixel, and the extension of the red color filter is provided across a boundary between the red subpixel and the green subpixel adjacent to the red subpixel or across a boundary between the red subpixel and the blue subpixel adjacent to the red subpixel.

3. The light emitting display device according to claim 1, wherein:
the color filter comprises a red color filter, a green color filter, and a blue color filter corresponding to the red subpixel, the green subpixel, and the blue subpixel, respectively; and
among overlapping areas of the red color filter, the green color filter, and the blue color filter with the bank, an overlapping area of the red color filter with the bank is largest.

4. The light emitting display device according to claim 2, further comprising a dummy red color filter overlapping at least one of the non-emission portion of the green subpixel or the non-emission portion of the blue subpixel.

5. The light emitting display device according to claim 4, wherein:
the red color filter comprises a first region overlapping the emission portion of the red subpixel and a second region overlapping the non-emission portion of the red subpixel, the first region and the second region are connected to each other, and the second region has a shape surrounding the first region; and
the second region is connected to the dummy red color filter.

6. The light emitting display device according to claim 4, wherein the reflective layer overlaps the red color filter at the non-emission portion of the red subpixel and overlaps the dummy red color filter.

7. The light emitting display device according to claim 1, wherein the reflective layer is in contact with an upper surface of the bank.

8. The light emitting display device according to claim 1, wherein the reflective layer is in contact with an upper surface of the encapsulation layer.

9. The light emitting display device according to claim 1, wherein the reflective layer is located in contact with a lower surface of the color filter.

10. The light emitting display device according to claim 1, further comprising a light shielding layer located on the encapsulation layer and overlapping the non-emission portion,
wherein the light shielding layer overlaps at least a portion of the bank.

11. The light emitting display device according to claim 1, wherein the reflective layer comprises a reflective metal.

12. The light emitting display device according to claim 1, wherein:
the light emitting element comprises a first electrode and a second electrode facing each other, and an intermediate layer between the first electrode and the second electrode; and
the reflective layer is electrically separated from each of the first electrode and the second electrode.

13. The light emitting display device according to claim 12, wherein:
the intermediate layer of the light emitting element comprises an emission layer, a first common layer under the emission layer, and a second common layer above the emission layer; and
the reflective layer is in contact with or overlaps the first common layer or the second common layer.

14. The light emitting display device according to claim 1, wherein the bank comprises a black material.

15. The light emitting display device according to claim 12, wherein an edge of the first electrode is located at the non-emission portion and is covered by the bank.

16. A light emitting display device comprising:
a substrate comprising a first subpixel, a second subpixel and a third subpixel, each having an emission portion and a non-emission portion;
a bank provided at the non-emission portion of each of the first subpixel, the second subpixel, and the third subpixel;
a light emitting element provided at each of the first subpixel, the second subpixel, and the third subpixel;
an encapsulation layer covering the light emitting element of each of the first subpixel, the second subpixel, and the third subpixel;
a color filter located on the encapsulation layer and overlapping the emission portion of each of the first subpixel, the second subpixel, and the third subpixel; and
a reflective layer located between the bank and the color filter and configured to reflect external light that passes through the color filter back toward the color filter.

17. The light emitting display device according to claim 16, wherein:
the color filter comprises a first color filter, a second color filter, and a third color filter corresponding to the first subpixel, the second subpixel, and the third subpixel, respectively,
further comprising a dummy color filter configured to transmit light of a same color as the first color filter at an area of the non-emission portion overlapping the reflective layer.

18. The light emitting display device according to claim 17, wherein the dummy color filter is positioned at a same layer as the first color filter, the second color filter, and the third color filter.

19. The light emitting display device according to claim 17, wherein among overlapping areas of the first color filter, the second color filter, and the third color filter with the non-emission portion, an overlapping area of the first color filter with the non-emission portion is largest.

20. The light emitting display device according to claim 17, wherein light directed from below the color filter toward the color filter in an initial state has wavelengths that are optically complementary to wavelengths of light configured to pass through the first color filter.
